(19) United States
(12) Patent Application Publication
(10) Pub. No.: US 2025/0138577 A1
(43) Pub. Date: May 1, 2025

(54) METHOD OF MONITORING A CLOCK SIGNAL

(71) Applicant: Arm Limited, Cambridge (GB)

(72) Inventors: Amit Chhabra, Noida (IN); Rainer Herberholz, Great Abington (GB)

(73) Assignee: Arm Limited, Cambridge (GB)

(21) Appl. No.: 18/925,518

(22) Filed: Oct. 24, 2024

(30) Foreign Application Priority Data
Oct. 27, 2023 (IN) 202311073299
Oct. 27, 2023 (IN) 202311073432
Dec. 18, 2023 (IN) 202311086442
Mar. 20, 2024 (GB) 2403978.6
Mar. 20, 2024 (GB) 2403979.4
Mar. 20, 2024 (GB) 2403986.9

(51) Int. Cl. G06F 1/14; G01R 31/317

(52) U.S. Cl. CPC G06F 1/14; G01R 31/31727

(57) ABSTRACT

The present techniques relate to monitoring of a clock signal at a circuit and disclose a method comprising: receiving, at a delay monitor, a gateable clock signal; analysing, by the delay monitor, the clock signal to generate a measurement value, wherein the measurement value is responsive to the clock signal and/or a voltage; and comparing, by the delay monitor, the measurement value with a threshold; and storing the measurement value for further analysis when the comparison does not meet the threshold; or discarding the measurement value when the measurement value meets the threshold.

### TECHNICAL FIELD

The present techniques relate to monitoring of a clock signal at a circuit.

### BACKGROUND OF THE DISCLOSURE

Some computer circuits (e.g., a central processor unit (CPU) or graphics processor unit (GPU)) may require different voltages and clock frequencies during operation to deliver performance with energy efficiency.

For example, there may be circumstances that require an increase or decrease in voltage and/or clock frequency. These increases or decreases are sometimes in response to a change in another of the operating parameters, such as a voltage droop or an over-current alert, or they may be made by choice to tune the performance of the circuit. Whichever the circumstances, monitoring of the operating parameters, such as voltage and/or clock frequency is helpful in determining the progress of, and controlling the operation of, the operating characteristics of the circuit.

### SUMMARY OF THE DISCLOSURE

The present techniques relate to addressing the monitoring of the operating characteristics of such circuits.

In a first approach there is provided A method of monitoring a clock signal at a circuit, the method comprising: receiving, at a delay monitor, a gateable clock signal; analysing, by the delay monitor, the clock signal to generate a measurement value, wherein the measurement value is responsive to the clock signal and/or a voltage; and: comparing, by the delay monitor, the measurement value with a threshold; and storing the measurement value for further analysis when the comparison does not meet the threshold; or discarding the measurement value when the measurement value meets the threshold.

The method may comprise: generating a plurality of measurement values during a sampling period, and may further comprise generating, by the delay monitor, a measurement value for each clock cycle within the sampling period.

The method may comprise: generating statistical data, wherein the statistical data is based on the plurality of measurement values generated during the sampling period, and may further comprise, determining, by the delay monitor, from the statistical data, the maximum measurement value and/or minimum measurement value during the sampling period.

The method may comprise sending, by the delay monitor, the statistical data to a system control processor.

The measurement value may correspond to the number of gates traversed by the clock signal in a delay line of the delay monitor during a clock cycle, and wherein the measurement value corresponds to the output of an encoder.

The threshold may be a programmable threshold, and wherein the method may comprise: receiving, by the delay monitor, the programmable threshold from firmware.

The voltage may be supplied by a power distribution network.

The method may comprise: determining a dynamic voltage variation based on or in response to the measurement value.

The delay monitor and the circuit may by driven by the same gateable clock signal.

In a further approach there is provided a circuit for monitoring a clock signal, the circuit comprising a delay monitor configured to: receive a gateable clock signal; analyse the clock signal to generate a measurement value, wherein the measurement value is responsive to the clock signal and/or a voltage; compare the measurement value with a threshold; and in response to the comparison, the delay monitor is to: capture the measurement value for further analysis when the comparison does not meet the threshold; or discard the measurement value when the measurement value meets the threshold.

The delay monitor may be further configured to generate a plurality of measurement values during a sampling period, and where the delay monitor may be further configured to generate a measurement value for each clock cycle within the sampling period.

The delay monitor may be further configured to generate statistical data, wherein the statistical data is based on the plurality of measurement values generated during the sampling period, and the delay monitor may be further configured to determine, from the statistical data, the maximum measurement value and/or minimum measurement value during the sampling period.

The delay monitor may be further configured to send the statistical data to a system control processor.

The measurement value may correspond to the number of gates traversed by the gated clock signal in a delay line of the delay monitor during a clock cycle, and wherein the measurement value corresponds to the output of an encoder.

The threshold may be a programmable threshold, and wherein the delay monitor is further configured to receive the programmable threshold from firmware.

The voltage may be supplied by a power distribution network.

In a further approach there is provided a processor comprising the above circuitry.

In a further approach there is provided a system comprising: the above circuitry, implemented in at least one packaged chip; at least one system component; and a board, wherein the at least one packaged chip and the at least one system component are assembled on the board.

In a further approach there is provided a chip-containing product comprising the above system assembled on a further board with at least one other product component.

In a further approach there is provided a non-transitory computer-readable medium to store computer-readable code for fabrication of the above circuitry.

The method and circuit according to the present technology may thus be used in monitoring of operating parameters at a circuit, and that method may be realised in the form of a non-transitory computer readable medium comprising a structure of data and imperatives operable to cause a device to construct a set of electronic logic components which, when embedded in an electronic device and activated thereon, cause the electronic device to perform the steps of the method of the present technology as described hereinabove.

As will be clear to one of skill in the art, a hybrid approach may also be taken, in which hardware logic, firmware and/or software may be used in any combination to implement the present technology.

### BRIEF DESCRIPTION OF DRAWINGS

Implementations of the disclosed technology will now be described, by way of example only, with reference to the accompanying drawings, in which:

FIG. 1 schematically shows a diagram of a system having a clock control circuit;

FIG. 2 schematically shows a diagram of a delay monitor of the system of FIG. 1;

FIG. 3 schematically shows a diagram of an example delay line of the delay monitor of FIG. 2;

FIG. 4 schematically shows a timing diagram for non-gated and gated clock signals;

FIG. 5 schematically shows a timing diagram for a clock signal and corresponding measurement values;

FIG. 6 schematically shows a simplified flow diagram of a method of operation according to an implementation of the present techniques; and

FIG. 7 illustrates a system and a chip-containing product.

### DETAILED DESCRIPTION

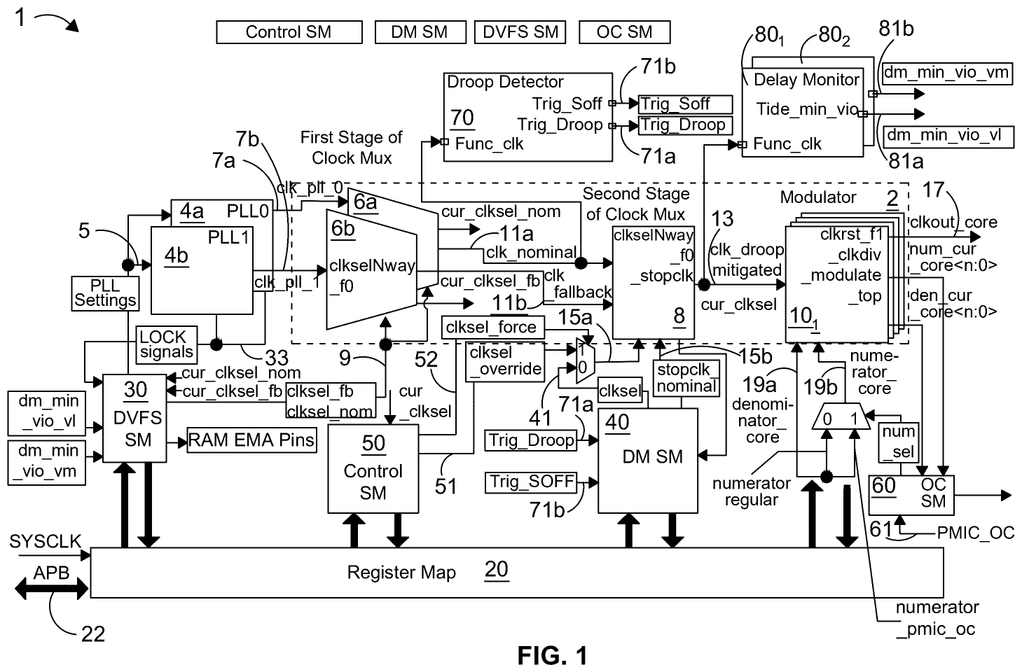

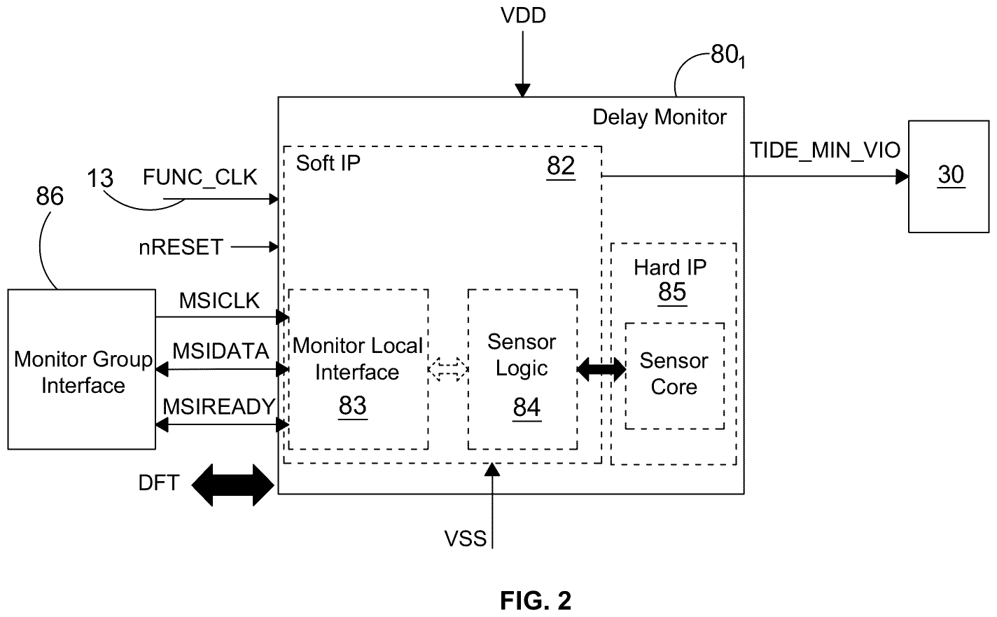

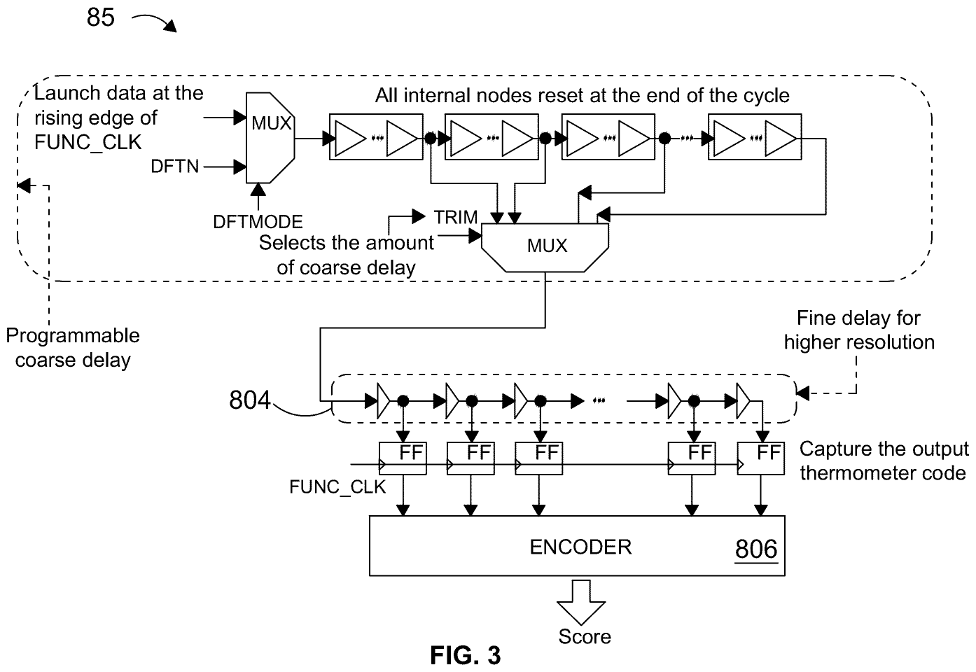

FIG. 1 schematically shows a diagram of a circuit system 1 (e.g., of a system on chip) having a clock control circuit 2 and where FIGS. 2 and 3 schematically show features of the clock control circuit 2 in more detail.

It will be appreciated that the term “signal” is non-limiting and may take any form to convey a message, operation, or information to a component (hardware or software), where, for example, the signal may comprise one or more bits, a logic value (e.g., high, or low), or a voltage value etc. In embodiments the signal may comprise a clock signal having a particular frequency and or level (e.g., voltage level).

Furthermore, the signals provided to a component (e.g., hardware or software) to control the operation thereof (e.g., to select a particular clock signal) or to change properties thereof (e.g., to cause the component to operate in a certain way) may be referred to as a “control signal.”

In the present example, the control signals provided to the clock control circuit 2 may be provided from circuitry comprising (e.g., configured to operate as) state machines 30, 40, 50, 60 as will be described in detail below. Furthermore, clock signals may be provided to clock pins of the components of the clock control circuit 2. The clock control circuit 2 and clock sources and other state machines 30, 40, 50, 60 are taken to operate as a clock control state machine (CCSM), and form part of a clock distribution network (CDN) for generating an output clock signal which may be used by another system (e.g., a CPU or GPU).

The state machines may be implemented as hardware and/or software. In embodiments, the state machines are implemented as fixed function hardware.

The state machines may access, for example, storage to generate the signals to control the clock control circuit 2 (or other state machines) in response to the data/values (e.g., one or more bits) therein. In the present illustrative example, the storage comprises a plurality of registers, where one or more of the registers may be programmable.

The state machines may access (read and/or write) registers of register map 20 as required for a particular operation. The register map 20 may be accessed by components of the system 1.

The registers may also be accessed by, for example, firmware (e.g., during start-up), where the firmware may access the registers, for example, via an interface such as an Advanced Peripheral Bus (APB), which may be part of the Advanced Microcontroller Bus Architecture (AMBA) protocol family, although the claims are not limited in this respect.

Clock control circuit 2 receives a plurality of clock signals from clock sources 4ₙ (where “n” is an integer, n>1), where clock source₀ 4a & clock source₁ 4b, are shown in FIGS. 1-3.

In the present embodiment the clock sources 4a & 4b are phased locked loops (PLL), where each clock source provides a clock signal having a voltage and frequency.

However, the claims are not limited to the clock sources being PLL and in a further embodiment the clock source 4b may be a derivative of clock source 4a. For example, the clock source 4b may be a divided clock of the first clock source 4a. In a still further embodiment, the first and second clock sources 4a & 4b may be fixed clock sources from different units.

In the present embodiment, where the clock sources 4a & 4b are PLLs, each clock source 4a/4b receives one or more PLL signals 5 to configure the properties of the clock signals and supplies the clock signal 7a, 7b to the clock control circuit 2.

In the present illustrative example, a Dynamic Voltage and Frequency Scaling (DVFS) state machine 30 provides the PLL signals 5. The properties of the PLL signals may be set in response to requests from the control state machine 50 dependent, for example, where a request from control state machine may request the DVFS state machine 30 to, for example, perform a set of tasks that are required to configure the PLL in accordance with a DVFS sequence. The DVFS state machine 30 may receive “LOCK signals” from the one or more clock sources 4a & 4b to confirm that the properties of the respective clock signals are configured as expected in response to the one or more PLL signals (e.g., that a required phase lock is achieved).

Furthermore, the control state machine 30 may send requests to the DVFS state machine 30 to increase or decrease a target voltage/operating point (OPP) dependent on an existing OPP (e.g., as defined in one or more registers).

The control state machine 50 may also request the DVFS state machine to perform other tasks such as, for example, to configure a RAM (random access memory) EMA (extra margin adjustment), where the DVFS state machine 30 drives the EMA related pins of the RAM, and where the RAM pin states are dependent on, for example, the type of bitcell, memory architecture and the voltage of operation.

The clock control circuit 2 comprises a first clock path stage comprising multiplexers 6a, 6b, which are controlled, responsive to clock select signal 9 (depicted as clksel_nom or clksel_fb in FIGS. 1-3), to cause the first stage to supply a first clock signal 11a which is designated as a nominal clock signal (depicted as clk_nominal) and to supply a second clock signal 11b which is designated as a fallback clock signal (depicted as clk_fallback) to a second clock path stage 8.

Although only two clock sources 4a & 4b are depicted in FIG. 1, the claims are not limited in this respect and multiple clock sources may be provided, where each clock source may provide clock signals which may be used for a particular DVFS scheme. As an illustrative example, a first DVFS scheme may use a first nominal clock signal from a first clock source and first fallback clock signal from a second clock source and a second DVFS scheme may use a second nominal clock signal from third clock source and a second fallback clock signal from a fourth clock source, where the frequency of the nominal and fallback clock signals of the first DVFS scheme are different (e.g., higher or lower) than the respective nominal and fallback clock signals of the second DVFS scheme.

The nominal clock signal 11a comprises a relatively high frequency fast clock that may be provided to a processor (e.g., CPU or GPU) sub-system (e.g., core). The fallback clock signal 11a is a relatively low frequency slow clock that may be used when an event (e.g., a droop event) is detected.

In the present illustrative example, the DVFS state machine 30 provides the clock select signal 9 to drive the nominal clock signal or the fallback clock signal to the second clock path stage dependent on, for example, whether an event (e.g., a droop event) is detected. Since the effects of droop are more severe at higher clock frequencies and higher clock voltages, the fallback clock signal, which is to be selected by the clock mux during droop events, has a lower frequency than the nominal clock signal. In an example, the nominal clock signal has a frequency of 3.5 GHZ, and the fallback clock signal has a lower frequency of, for example, 3 GHZ.

The second clock path stage 8 provides a clock signal 13 to a modulator stage, where the modulator stage comprises a plurality of modulator units 10₁-10ₘ (where “m” is an integer)

In the present example the clock signal 13 is provided from the second clock path stage 8 responsive to signals 15a/15b, where the signals 15a/15b may be provided in accordance with a droop mitigation scheme. Such a droop mitigation scheme may mitigate against the negative effects of voltage droop. In this sense, the output of the clock circuit (output clock signal) is taken to be a mitigated clock signal (depicted as clk_droop_mitigated). Thus, it will be seen that the output clock signal corresponds to the clock signals of the DVFS scheme in use, and the properties of the clock signals of the DVFS schemes (e.g., a first DVFS scheme, second DVFS scheme or otherwise) can be configured by the DFVS state machine 30.

In the present illustrative example, the signals 15a/15b are provided by a droop mitigation state machine 40 and a control state machine 50 dependent on the properties of a droop event.

For example, the droop mitigation state machine 40 and control state machine 50 are used to provide a clock control signal 15a to cause the second clock path stage 8 to select and provide the nominal clock signal 11a or the fallback clock signal 11b to the modulator stage as the mitigated clock signal 13. For example, the droop mitigation state machine 40 is to provide a “clksel” signal 41 which is to cause the second stage 8 to provide either the nominal clock signal 11a or the fallback clock signal 11b to the modulator stage depending on the value of the “clksel” signal 41, and where the control state machine 50 is to provide a “clksel_override” signal 51 which is to override the clksel signal 41, where one of the clksel signal 41 or clksel_override 51 are selected in response to a clksel_force signal 52, which in the present illustrative example is used to control a multiplexer to select between the signals 41 and 51.

Furthermore, the droop mitigation state machine 40 is to provide signal 15b to prevent any clock signal to be provided to the modulator stage on detection and for the duration of a particular event (e.g., a droop event).

The modulator units 10₁-10ₘ each modulate the mitigated clock signal 13 (e.g., using average power modulation) and provide, responsive to modulator signals 19a/19b the modulated clock signal 17 to a particular sub-system as an output clock signal (e.g., to a core (not shown)) of a processor unit (not shown).

The modulator units 10₁-10ₘ may operate independently of each other, so as to, for example, independently provide average power modulation per core of a multi-core system. In the present illustrative example, the clock control circuit 2 comprises a modulator unit 10ₘ per core (not shown))

The modulator units 10₁-10ₘ may be individually selected and/or the settings thereof may be controlled responsive to modulator control signals (hereafter “modulator signal(s)”, “control signal” or “signal(s)”). The modulator signals 19a/19b may be used to select the modulator unit 10₁ to 10ₘ which is used to modulate the mitigated clock signal 13 and/or to identify the sub-system to which the clock signal 17 is to be provided. The modulator signals 19a/19b may also define how the modulator is to modulate the mitigated clock signal 13. In the present illustrative example, the modulator signal 19a comprises a denominator value which may be obtained from a register (e.g., via register map 20). The modulator signal 19b comprises a numerator value (e.g., depicted as numerator_regular or numerator_pmic_oc), which may be obtained from registers. In the present illustrative embodiment, the fraction of clock pulses present in the output clock signal 17 relative to the mitigated clock signal 13 are taken to be the numerator/denominator.

The values of the numerator and denominator can be programmed independently for each modulator unit and stored in the programmable register(s) of register map 20 where the modulator uses to the numerator and denominator values to modify the mitigated clock signal 13 (e.g., to change the frequency) to provide the output clock signal 17.

In the present illustrative example, modulator signal 19b may be selected to be numerator_pmic_oc by an over-current state machine 60, where the over-current state machine 60 provides hardware support for current demand reduction, for example, in the case of a signal 61 (e.g., a warning signal (e.g., a pre-over-current signal)) from a Power Management IC (PMIC) (not shown in FIG. 1).

As an illustrative example, the over-current state machine 60 receives warning signal 61 and asserts modulator signal 19b to be ‘numerator_pmic_oc’ as opposed to ‘numerator_regular’ when the warning signal 61 is received from the power management PMIC, where the numerator_pmic_oc value changes the modulator settings to provide a modulated clock signal 17 which reduces the current demand by a sub-system (not-shown) receiving the modulated clock signal 17 in comparison to ‘numerator_regular’ value for the numerator.

In embodiments the modulator units 10₁-10ₘ may not alter the clock frequency of the mitigated clock signal 13, but may suppress some of the clock pulses e.g., to reduce the current demand of the sub-system.

As described above the state machines 30, 40, 50 and/or 60 may access values/data in registers of register map 20 to generate the control signals to control the clock control circuit 2 (or other state machines) in response to the data/values (e.g., one or more bits) therein.

In embodiments the PMIC may be used to set the voltage (VDD) provided to one or more sub-systems (e.g., a processor unit) from a power delivery network (PDN) (not shown).

The properties (e.g., level) of the voltage (VDD) provided to the sub-system(s) may be controlled by the PMIC in response to instructions e.g., from firmware (e.g., running on the system control processor (SCP)). As in an illustrative example, the level of the VDD may be required to be relatively high when the output clock signal 17 corresponds to a relatively high frequency (e.g., a frequency of a nominal clock signal of a first DVFS scheme) and can be reduced when the output clock signal corresponds to a relatively low frequency (e.g., a frequency of a nominal clock signal of a second DVFS scheme).

In the present illustrative example, values/data in registers of the register map 20 can be used to configure the settings of state machines in the programmable registers.

Examples what the data/values in the registers in the present illustrative embodiments include, but are not limited, to define:
architectural level inputs for the nominal PLL (or clock source);
a bit(s) for enabling the nominal PLL (or clock source);
settings for the clock generator that drives the frequency of a nominal clock signal and/or the frequency of a fallback clock signal;
architectural level inputs for the fallback PLL (or clock source);
a bit(s) for enabling the fallback PLL (or clock source);
the settings for the clock generator that drives the fallback frequency;
timer that runs on SYSCLK. It is used to ascertain voltage stability for both the memory and the logic supply;
a strategy that CCSM uses to determine voltage stability;
a strategy for droop mitigation;
whether a mitigation strategy is enabled;
the mitigation strategy on a droop event;
overrides the existing droop mitigation of stopping the clock during a DVFS transition;
the settings of the Modulator;
the value of the denominator of the Modulator;
the value of the numerator of the Modulator in regular use case;
the value of the numerator of the Modulator when there is a pre-over-current warning from the PMIC;

It will be appreciated that the above examples of data/values in the registers are not exhaustive and are for illustrative purposes only.

As described above, the various state machines 30, 40, 50, 60 may interact and influence the control and/or clock signals generated by one another.

Additionally, or alternatively, the system 1 may comprise further components (hardware and/or software components) that may interface with the various state machines 30, 40, 50, 60 and vice versa to influence the control and/or clock signals generated thereby. For example, the various state machines of the CCSM may interface with droop detectors or delay monitors to carry out droop mitigation and DVFS.

As an illustrative example, system 1 comprises one or more delay monitors 80, two of which 80₁ & 80₂ are depicted in FIG. 1. The delay monitors 80 may be located in different locations of a processor (e.g., CPU or GPU), or even outside the physical perimeter of a processor (e.g., CPU or GPU), with each delay monitor to measure the delays e.g., in a clock cycle of a clock supplied to components at the respective locations from a clock distribution network.

The Delay Monitor measures, for example, the number of delays a signal propagates within a clock cycle. That depends on how much time the signal is given (clock) and the speed of propagation (gate delay). The latter is a function of silicon process skew, supply voltage and temperature. For a component in the field the silicon skew may be known e.g. from characterisation tests performed post fabrication. Thus voltage, from the PDN, may have a substantive impact on gate delay. The delay monitor can thus be used either to measure the clock period if voltage is known, or to measure voltage if the clock period is known.

In response to an event (e.g., a delay in the clock signal at the monitored location vs an expected delay), a delay monitor that detects the event generates an alert (or violation) signal, where delay monitor 80₁ generates an alert signal 81a and delay monitor 80₂ generates alert signal 81b. In the present illustrative example of FIG. 1, the alert signal 81a (depicted as dm_min_vio_vl in FIG. 1) comprises a delay monitor alert signal for a logic supply being monitored and the alert signal 82a depicted as (dm_min_vio_vm in FIG. 1) comprises a delay monitor alert signal for a memory bitcell supply being monitored. However, it will be appreciated that the claims are not limited in this respect, and delay monitors may be provided to generate alert signals for many different areas of a processor (e.g., CPU/GPU sub-system).

The alert signals may be used as inputs to DVFS state machine 30 to, for example, calibrate DVFS setpoints, manage DVFS transitions and/or to allow the DVFS state machine to check for voltage stability while performing transitions.

Looking now in more detail at the delay monitors, delay monitor 80₁ is schematically shown in the high-level diagram of FIG. 2, and comprises soft IP, which in the present illustrative example, comprises a local interface 83 and sensor logic 84.

The soft IP outputs (to DVFS SM in the present illustrative embodiment) an alert (e.g., violation or non-violation) signal TIDE_MIN_VIO which is indicative of the stability of VDD. In embodiments TIDE_MIN_VIO may be synchronous with the nominal clock signal 13. TIDE_MIN_VIO will be described in further detail below.

The delay monitor also comprises hard IP 85, which in the present illustrative example comprises a sensor core 85, which may be tied, for example, to the monitored locations (e.g., CPU/GPU) logic voltage supply before any power gates at the architectural level.

The sensor core 85 may comprise one or more delay lines connected to a particular area of the sub-system (e.g., a top metal or bottom metal area) to measure delays in that particular area and output a measurement value or score (hereafter “measurement value”). An example of the delay lines used by sensor core 85 is depicted in FIG. 3.

A monitor group interface 86 may provide communications between the local interfaces of the respective delay monitors 80n and may send/receive signals to/from each of the local interfaces 83. Each of the delay monitors may be activated independently of each other.

In operation, the delay monitor 80₁ quantifies a delay within a clock cycle and generates one or more measurement values related to the quantified delay, and may generate one or more alert signals (e.g., violation or non-violation signals) responsive to the one or more measurement values.

The present techniques may also use the one or more measurement values responsive to one or more both a clock signal from CDN and/or voltage from the PDN may be used to determine whether the voltage is selected appropriately for the applied frequency. As a measurement value may be taken for each clock cycle, the impact of dynamic voltage variation may be determined from one or more measurement values at the resolution that matters to the function of a digital circuit. Whilst the techniques below generally describe the measurement values responsive to clock signal, it will be appreciated that the one or more measurement values generated or captured by the delay monitor are responsive to a combination of one or both of a clock signal from the CDN and a voltage from the PDN.

An example of the sensor core 85 which may be used in accordance with the present techniques is illustratively shown in FIG. 3. It will be appreciated that the delay lines are only provided as an illustrative example and the claims are not limited to the delay lines of FIG. 3.

The sensor core 85 comprises a coarse delay line 802, a fine delay line 804 and an encoder 806.

The delay monitor works on the principle of a delay line that captures the delay traversed by a set of gates in each FUNC_CLK cycle.

The coarse delay line 802 is programmable (e.g., by software) to allow flexibility in the obtained value of a measurement value, where the amount of delay contributed by the course delay line 802 can be adjusted using TRIM bits. If TRIM=0'x00, then only a minimum fixed delay is present. As the value of TRIM increases, the amount of the delay from the course delay line 802 increases and hence the value of the measurement value will reduce.

A measurement value is provided by the output of the encoder where the measurement value corresponds to a count of the number of fine gate stages traversed in the fine delay line 804 during a sampling period, wherein the sampling period corresponds to a predetermined number of clock cycles. The output may be measured every output clock cycle (e.g., FUNC_CLK) of a clock distribution network and averaged over a predetermined number of clock cycles for analysis.

In operation, the sensor core of the Hard IP 85 captures this value for each FUNC_CLK cycle when the Delay Monitor 80 is active. This n-bit value is then processed by the sensor logic 84 and statistical data and/or one or more alert signals provided as the output.

The sensor logic 84 can process the measurement values to build statistical information or data, hereafter “tides”, regarding the collected measurement values (e.g. maximum/minimum values over a sampling period) as well as changes in the measurement value between neighbouring clock cycles, hereinafter referred to as “slope” (e.g. maximum value of falling slope or maximum value of rising slope). The tides can then be used to check that the system 1 (or portions thereof) are operating as expected, and to cause an alert signal when any unexpected or undesired operation is detected. The delay monitor may analyse clock cycles of the clock signal CLK until the end of a sampling period and/or until the delay monitor is instructed to stop, for example by firmware.

The delay monitor may produce statistical data from the captured measurement values, and may transmit the statistical data to e.g. the SCP for further processing and analysis. In examples, the statistical data comprises:
Minimum measurement value, or TIDE_MIN_SCORE
Maximum value of falling slope, or TIDE_MAX_FALL_SLOPE
Maximum measurement value, or TIDE_MAX_SCORE
Maximum value of rising slope, or TIDE_MAX_RISE_SLOPE

TIDE_MIN_SCORE is the minimum value of the measurement value in a given sampling period, TIDE_MAX_SCORE is the maximum value of the measurement value in the given sampling period, TIDE_MAX_FALL_SLOPE is the maximum value of the falling slope in a given sampling period and TIDE_MAX_RISE_SLOPE is the maximum value of the falling slope in a given sampling period. These values can be used for example to determine the effectiveness of a droop mitigation technique or when managing DVFS sequences.

The delay monitor can be used to analyse, and generate statistical data from a non-gated clock signal or a gated clock signal. By “gated clock signal” it is meant a clock signal having one or more suppressed clock pulses. The delay monitor stores in memory (e.g., in a register) a configuration parameter CLK_GATED_CFG. When the delay monitor is used to monitor a non-gated clock signal, the configuration parameter CLK_GATED_CFG is set to 0, whereas when the delay monitor is used to monitor a gated clock signal, the configuration parameter CLK_GATED_CFG is set to 1.

The delay monitor generates statistical data based on the value of CLK_GATED_CFG. When CLK_GATED_CFG is set to 0, the statistical data generated by the delay monitor comprises TIDE_MIN_SCORE, TIDE_MAX_FALL_SLOPE, TIDE_MAX_SCORE and TIDE_MAX_RISE_SLOPE. When CLK_GATED_CFG is set to 1, the statistical data generated by the delay monitor comprises TIDE_MIN_SCORE and TIDE_MAX_FALL_SLOPE (TIDE_MAX_SCORE and TIDE_MAX_RISE_SLOPE are not available when CLK_GATED_CFG is set to 1).

As an illustrative example of an alert signal generated by the delay monitor, AVAL_MIN_SCORE may be taken to be a minimum threshold of the measurement value. When the actual measurement value monitored by delay monitor (DMON_SCORE) falls below (or above, in other embodiments) the AVAL_MIN_SCORE, the delay monitor may generate an alert signal (e.g., TIDE_MIN_VIO). In embodiments, firmware (e.g., running on the SCP) may set the value of the AVAL_MIN_SCORE.

It will be appreciated that the delay line 804 is only provided as an example of Hard IP 85 to provide a measurement value based on a clock signal.

The delay monitor can be used to monitor clock signals in multiple locations of circuitry.

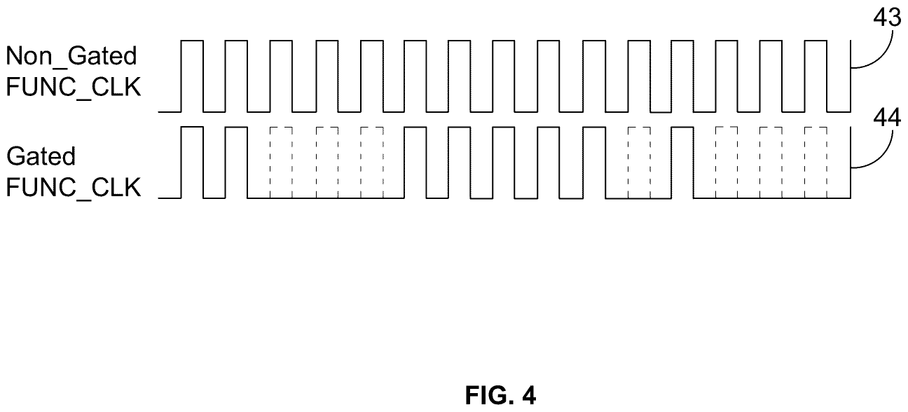

As an illustrative example FIG. 4 schematically shows a non-gated clock signal 43 and gated clock signal 44.

The non-gated clock signal 43 may be generated by the clock control circuit 2 for use by another system (e.g., a CPU or GPU). For example, the non-gated clock signal 43 may be the mitigated clock signal 13 depicted as clk_droop_mitigated in FIG. 1. The non-gated clock signal 43 may be input to a delay monitor when measuring the effectiveness of a droop mitigation technique or when managing DVFS sequences, for example.

In other examples, the clock signal output from the clock distribution network may be gated on the subsystem to which it is provided (e.g. using clock gate components or logic). For example, the gated clock signal 44 may be the mitigated clock signal 13 which has been gated for use by another system (e.g., a CPU or GPU). Use of a clock gating mechanism to suppress one or more clock pulses will reduce power use by said another system. FIG. 4 shows example gated clock signal 44. The gated clock signal 44 may be input to a delay monitor and monitored to identify local IR hotspots, for example.

In examples a delay monitor (e.g., the delay monitor 80₁) is used to monitor clock signals, such as the clock signals shown in FIG. 4. As noted above, the delay monitor works on the principle of a delay line that captures the delay traversed by a set of gates in each FUNC_CLK cycle. The delay monitor provides the output of the encoder as a measurement value or score, and over time collects statistical data (“tides”) regarding the collected measurement values as well as changes in the measurement value between neighbouring clock cycles (“slope”).

When the delay monitor is used to monitor a non-gated clock signal, the configuration parameter CLK_GATED_CFG is set to 0 and the statistical data generated by the delay monitor comprises TIDE_MIN_SCORE, TIDE_MAX_FALL_SLOPE, TIDE_MAX_SCORE and TIDE_MAX_RISE_SLOPE. When the delay monitor is used to monitor a gated clock signal, the configuration parameter CLK_GATED_CFG is set to 1 and the statistical data generated by the delay monitor comprises TIDE_MIN_SCORE and TIDE_MAX_FALL_SLOPE.

When the FUNC_CLK of the delay monitor is gated, and e.g. a clock gating mechanism is used to reduce power, some measurement values can be arbitrarily high. Such high values may significantly skew the statistics generated by the delay monitor (in particular, the maximum measurement value over a sampling period), such that the statistics will not be useful. Methods and techniques disclosed herein can mitigate against such negative effects of arbitrarily high measurement values.

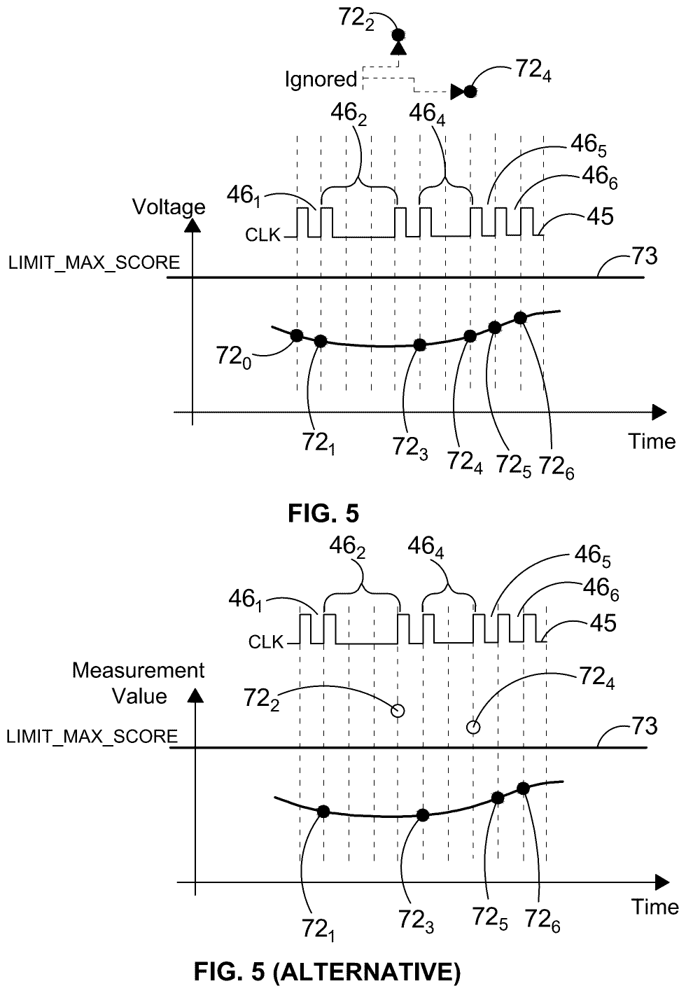

FIG. 5 schematically shows a timing diagram of the analysis of a gated clock signal 45 by the delay monitor for a plurality of clock cycles 46.

The delay monitor is configured to receive the gated clock signal CLK 45 (as input FUNC_CLK in FIG. 2), analyse the clock signal to generate a plurality of measurement values 72, compare each measurement value 72 with the threshold 73 (LIMIT_MAX_SCORE) and, in response to the comparison, perform actions (i.e. capturing or discarding the respective measurement values 72). The threshold 73 (LIMIT_MAX_SCORE) may be used and the value thereof defined (e.g. in storage) when gated the configuration parameter CLK_GATED_CFG is set to 1.

The clock signal 45 comprises a plurality of clock cycles 46. During each clock cycle 46 the clock signal 45 comprises a rising edge, a high voltage value, a falling edge and a low voltage value. Each clock cycle ends when the next clock cycle starts i.e. when there is a rising edge which begins the next clock cycle. In examples the delay monitor determines a measurement value or “score” 72 at each clock cycle 46.

In an example the delay monitor receives the clock signal 45 and determines a first measurement value 72₁ corresponding to the first clock cycle 46₁. As shown in FIG. 5, the first measurement value 72₁ is less than the LIMIT_MAX_SCORE threshold 73, so the threshold has not been met. Therefore, the action taken in respect of the first measurement value 72₁ is that the first measurement value 72₁ is captured by the delay monitor. In examples such capturing comprises storing, by the delay monitor, the measurement value 72₁ for further analysis. The sensor core of the Hard IP 85 may capture the measurement value.

The delay monitor next determines a second measurement value 72₂ corresponding to the second clock cycle 46₂. As shown in FIG. 5, the second clock cycle 46₂ is longer than the first clock cycle. In particular, the second clock cycle 46₂ is three times as long as the first clock cycle 46₁ due to gating i.e. suppression of some of the clock pulses. The longer second clock cycle 46₂ results in an increased measurement value 72₂ being produced by the delay monitor (the second measurement value 72₂ is greater than the first measurement value 72₁). This increase of measurement value can be explained by the clock signal having more time to reach a later delay stage during the second clock cycle 46₂, so that the encoder of the delay monitor will output a higher value. As shown in FIG. 5, the second measurement value 72₂ is greater than or equal to the threshold 73, so the threshold has been met. Therefore, it may be determined that the clock signal was gated during the second clock cycle 46₂ and the action taken is that the second measurement value 72₂ is discarded by the delay monitor. By “discarded” it is meant that the second measurement value 72₂ is not stored by the delay monitor.

The delay monitor next determines a third measurement value 72₃ corresponding to the third clock cycle 46₃. As shown, the third measurement value 72₃ is less than the threshold 73, so the threshold has not been met. Therefore the third measurement value 72₃ is captured by the delay monitor.

The delay monitor next determines a fourth measurement value 72₄ corresponding to the fourth clock cycle 46₄. As shown, the fourth measurement value 72₄ is greater than or equal to the threshold 73, so the threshold has been met. Therefore, it may be determined that the clock signal was gated during the fourth clock cycle 46₂ and the fourth measurement value 72₄ is discarded by the delay monitor.

The delay monitor next determines fifth and sixth measurement values 72₅ and 72₆ corresponding to the fifth and sixth clock cycles 46₅ and 46₆. As shown, the fifth and sixth measurement values 72₅ and 72₆ are less than the threshold 73, so the threshold has not been met. Therefore the fifth and sixth measurement values 72₅ and 72₆ are captured by the delay monitor.

The delay monitor may continue to analyse clock cycles of the clock signal CLK until the end of the sampling period and/or until the delay monitor is instructed to stop, for example by firmware.

At the end of the sampling period the delay monitor produces statistical data from the captured measurement values, and transmits the statistical data to the SCP for further processing and analysis. In particular, the statistical data comprises:
Minimum measurement value, or TIDE_MIN_SCORE
Maximum measurement value, or TIDE_MAX_SCORE

In this example, TIDE_MAX_RISE_SLOPE and TIDE_MAX_FALL_SLOPE are not available, since CLK is a gated clock signal and therefore the CLK_GATED_CFG parameter of the delay monitor is set to 1.

The threshold value of LIMIT_MAX_SCORE is used to discard all measurement values that are high due to a particular clock cycle being over a certain length. Such measurement values are discarded because they would otherwise misleadingly skew the statistical data as explained below. The statistical data generated by the delay monitor may be used by the SCP for determining the effectiveness of a droop mitigation technique or when managing DVFS sequences.

In the example of FIG. 5 outlined above the delay monitor chooses between one or more possible actions (i.e. capturing or discarding measurement values) based on whether or not a generated measurement value meets a threshold (in particular, LIMIT_MAX_SCORE). In the example of FIG. 5, the generated measurement value meets the threshold when the generated measurement value is greater than or equal to the threshold. Other embodiments are envisaged in which a generated measurement value meets a threshold when the generated measurement value falls below the threshold.

In the example of FIG. 5, the functional gated clock signal 45 includes plurality of clock cycles (46₁, 46₃, 46₅ and 46₆) having a first period (i.e. corresponding to the minimum period of the clock signal 45) while the remaining clock cycles (46₂ and 46₄) have longer periods. The longer clock cycles (46₂ and 46₄) have a longer period due to gating of the clock signal, which effectively suppresses clock pulses. In effect, the length of the clock cycles are random, and therefore the duration for which the delay is measured by the delay monitor is also random.

The minimum measurement value, or TIDE_MIN_SCORE (part of the statistical data determined by the delay monitor) will correspond to the lowest score of the shorter clock cycles (46₁, 46₃, 46₅ and 46₆). To prevent the maximum measurement value TIDE_MAX_SCORE from being dominated by the measurement values generated during longer clock cycles (46₂ and 46₄), the threshold value of LIMIT_MAX_SCORE is used to discard all measurement values that are high due to longer clock cycles. In short, use of LIMIT_MAX_SCORE to discard all measurement values that are excessively high due to extended clock cycles ensures the integrity and usefulness of the statistical data produced by the delay monitor.

The functionality described above provides a delay monitor which performs a monitoring process for a clock signal. The delay monitor quantifies the delay within a clock cycle and is used for integration within the CPU and GPU cores. The delay monitor samples the logic depth a signal traverses within each clock cycle and reports key statistics over a period to the SCP.

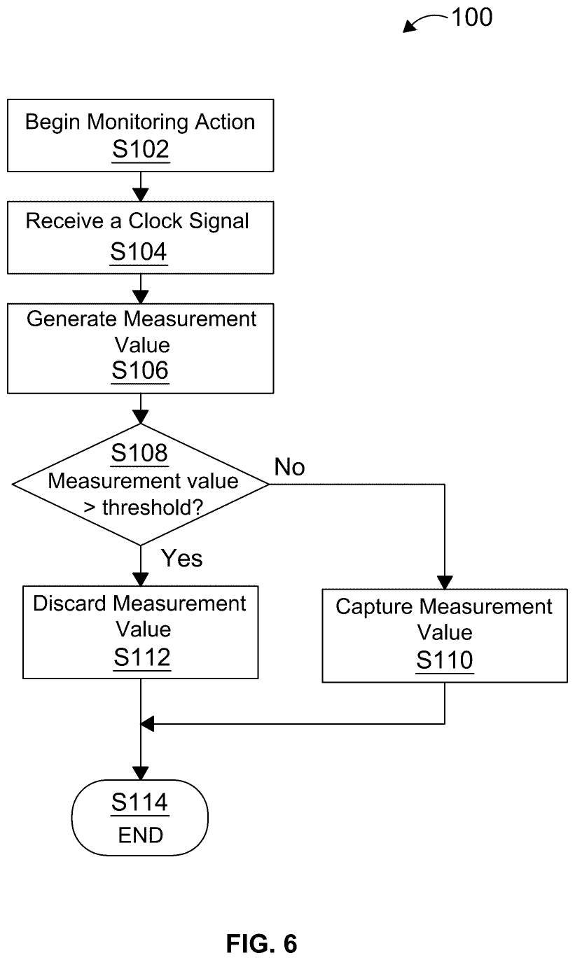

FIG. 6 schematically shows a simplified flow diagram of a method of operation 100 of the delay monitor of FIG. 2 according to one implementation of the present techniques.

The method 100 provides a method of monitoring a clock signal at a circuit. When a clock signal input to a delay monitor is gated for one or more clock cycles, the measurement values can be arbitrarily high during a subset of clock cycles. Consequently, the values of slope will be skewed by the higher measurement values, although the minimum measurement value will still be valid. The method 100 includes use of a threshold value to discard spurious measurement values that are high due to longer clock cycles, due for the example the clock signal being gated. Removing excessively high measurement values ensures the integrity and usefulness of the statistical data produced at the delay monitor, in particular the maximum measurement value TIDE_MAX_SCORE.

At S102 the delay monitor receives, e.g. from firmware, an instruction to begin a monitoring action or procedure. The monitoring action in the present illustrative example may be required because the correct operation of the circuit must be monitored or verified. For example, a sub-system (e.g., a CPU or GPU) may require a clock signal with a particular voltage and a particular frequency, and the SCP may need to check or verify that the clock signal at a particular point in the circuit is within operating tolerances.

At S104 the delay monitor receives a clock signal FUNC_CLK. The clock signal may be an output clock signal that has been generated by the clock distribution network for use by another system (e.g., a CPU or GPU). The clock signal is a gated clock signal i.e. the FUNC_CLK is gated for random FUNC_CLK cycles so that some of the clock pulses are suppressed.

At S106 the delay monitor generates a measurement value which is based on or is in response to the received clock signal. The delay monitor works on the principle of a delay line that captures the delay traversed by a set of gates in each FUNC_CLK cycle. The delay line comprises a coarse delay element and fine delay element as shown in FIG. 1. At the first rising edge of the clock signal, the signal is launched into the delay line. At the next rising edge of the clock signal it is determined where the signal has reached in the delay line. The coarse delay component is trimmable based on ‘TRIM’ bits, to ensure that the output signal is captured in the fine delay element. An overflow results from the signal reaching beyond the fine delay element during a single clock cycle, whereas an underflow results from the signal not reaching beyond the coarse delay element. The output of the fine delay element is input to an encoder. The measurement value is the numerical output of the encoder. As above, the measurement value output by the delay monitor is responsive to the frequency of the output clock signal of the clock distribution network, as well as to the VDD of the power delivery network.

At S108 the measurement value is compared with a threshold LIMIT_MAX_SCORE. The threshold LIMIT_MAX_SCORE is a programmable threshold and is stored in a register at the delay monitor. The threshold LIMIT_MAX_SCORE may be set by the delay monitor. Alternatively, the threshold LIMIT_MAX_SCORE may for example be received at the delay monitor from firmware.

In response to the comparison at S108, an action is performed. The particular action is based on the result of the comparison.

At S110, when the threshold is not met, i.e. when the measurement value is found to be less than LIMIT_MAX_SCORE, the measurement value is captured. By “captured” it is meant that the measurement value is stored by the delay monitor, for example for further analysis.

At S112, when the threshold is met (i.e. the measurement value is found to be greater than or equal to LIMIT_MAX_SCORE), it may be taken that the clock signal was gated during the measurement and the measurement value is discarded. By “discarded” it is meant that the measurement value is not stored by the delay monitor.

At S114 the process ends.

In the above example method 100 the delay monitor generates a single measurement value, corresponding to a single clock cycle. In further examples the method 100 can be repeated to generate a plurality of measurement values during a sampling period (e.g., p consecutive single clock cycles, where “p” is an integer greater than e.g. 2, 100 or 1000). In such examples a measurement value is generated by the delay monitor at each clock cycle and is either captured or discarded, depending on the comparison with LIMIT_MAX_SCORE.

When method 100 is repeated for a plurality of clock cycles then a series of measurement values are generated. In examples only a subset of the generated measurement values are captured, while the remaining generated measurement values are discarded. Statistical analysis can be performed by the delay monitor on the captured measurement values. The delay monitor can calculate, for a particular sampling period, statistical quantities such as the maximum and minimum measurement values over a number of CLK cycles. In some examples the delay monitor transmits the statistical quantities to the SCP for further analysis, rather than transmitting the plurality of generated measurement values and/or slope values, thereby saving processing power/time and/or bandwidth.

In the example method 100 outlined above the delay monitor chooses between one or more possible actions (i.e. capturing or discarding measurement values) based on whether a generated measurement value meets a threshold (in particular, LIMIT_MAX_SCORE). In the example of method 100, the generated measurement value meets the threshold when the generated measurement value is greater than or equal to the threshold. Other embodiments are envisaged in which a generated measurement value meets a threshold when the generated measurement value falls below the threshold.

In embodiments, the delay monitor may be driven by the same gateable clock that is driving the circuit being monitored. Such a configuration means that the delay monitor will detect outlying signals (e.g. signals that might result from the gated clock) and the delay monitor takes an action to mitigate the effects of those signals as described above (e.g. where measurement values resulting from the gated portion of the gated clock signal driving the delay monitor to be discarded).

In alternative embodiments the delay monitor may be driven by a different clock (e.g. a free running clock) to the circuit being monitored (which is driven by a gateable clock).

As above, the present techniques may use the one or more measurement values responsive to one or more both a clock signal from CDN and/or voltage from the PDN to determine whether the voltage is selected appropriately for the applied frequency. The dynamic voltage variation (or the impact which it has on operation of a component), may be determined from one or more measurement values at the resolution that matters to the function of a digital circuit. Whilst the techniques above generally describe the measurement values responsive to clock signal, it will be appreciated that the one or more measurement values generated or captured by the delay monitor are responsive to a combination of one or both of a clock signal from the CDN and a voltage from the PDN.

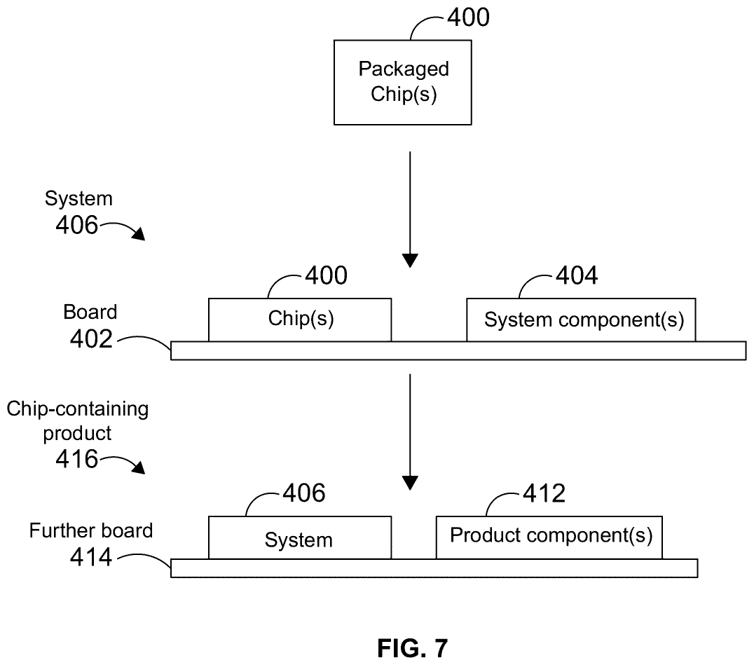

As shown in FIG. 7, one or more packaged chips 400, with the circuitry described above implemented on one chip or distributed over two or more of the chips, are manufactured by a semiconductor chip manufacturer. In some examples, the chip product 400 made by the semiconductor chip manufacturer may be provided as a semiconductor package which comprises a protective casing (e.g., made of metal, plastic, glass or ceramic) containing the semiconductor devices implementing the circuitry described above and connectors, such as lands, balls or pins, for connecting the semiconductor devices to an external environment. Where more than one chip 400 is provided, these could be provided as separate integrated circuits (provided as separate packages), or could be packaged by the semiconductor provider into a multi-chip semiconductor package (e.g., using an interposer, or by using three-dimensional integration to provide a multi-layer chip product comprising two or more vertically stacked integrated circuit layers).

In some examples, a collection of chiplets (i.e., small modular chips with particular functionality) may itself be referred to as a chip. A chiplet may be packaged individually in a semiconductor package and/or together with other chiplets into a multi-chiplet semiconductor package (e.g., using an interposer, or by using three-dimensional integration to provide a multi-layer chiplet product comprising two or more vertically stacked integrated circuit layers).

The one or more packaged chips 400 are assembled on a board 402 together with at least one system component 404 to provide a system 406. For example, the board may comprise a printed circuit board. The board substrate may be made of any of a variety of materials, e.g., plastic, glass, ceramic, or a flexible substrate material such as paper, plastic, or textile material. The at least one system component 404 comprise one or more external components which are not part of the one or more packaged chip(s) 400. For example, the at least one system component 404 could include, for example, any one or more of the following: another packaged chip (e.g., provided by a different manufacturer or produced on a different process node), an interface module, a resistor, a capacitor, an inductor, a transformer, a diode, a transistor and/or a sensor.

A chip-containing product 416 is manufactured comprising the system 406 (including the board 402, the one or more chips 400 and the at least one system component 404) and one or more product components 412. The product components 412 comprise one or more further components which are not part of the system 406. As a non-exhaustive list of examples, the one or more product components 412 could include a user input/output device such as a keypad, touch screen, microphone, loudspeaker, display screen, haptic device, etc.; a wireless communication transmitter/receiver; a sensor; an actuator for actuating mechanical motion; a thermal control device; a further packaged chip; an interface module; a resistor; a capacitor; an inductor; a transformer; a diode; and/or a transistor. The system 406 and one or more product components 412 may be assembled on to a further board 414.

The board 402 or the further board 414 may be provided on or within a device housing or other structural support (e.g., a frame or blade) to provide a product which can be handled by a user and/or is intended for operational use by a person or company.

The system 406 or the chip-containing product 416 may be at least one of: an end-user product, a machine, a medical device, a computing or telecommunications infrastructure product, or an automation control system. For example, as a non-exhaustive list of examples, the chip-containing product could be any of the following: a telecommunications device, a mobile phone, a tablet, a laptop, a computer, a server (e.g., a rack server or blade server), an infrastructure device, networking equipment, a vehicle or other automotive product, industrial machinery, consumer device, smart card, credit card, smart glasses, avionics device, robotics device, camera, television, smart television, DVD players, set top box, wearable device, domestic appliance, smart meter, medical device, heating/lighting control device, sensor, and/or a control system for controlling public infrastructure equipment such as smart motorway or traffic lights.

As will be appreciated by one skilled in the art, the present technology may be embodied as a method, a circuit or a computer readable medium comprising data and imperatives to cause construction of a circuit. Accordingly, the present technique may take the form of an entirely hardware embodiment, an entirely software embodiment, or an embodiment combining software and hardware. Where the word “component” is used, it will be understood by one of ordinary skill in the art to refer to any portion of any of the above embodiments.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally, or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the present techniques. Alternatively, or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the present techniques. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

In the present application, the words “configured to . . . ” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

In the present application, lists of features preceded with the phrase “at least one of” mean that any one or more of those features can be provided either individually or in combination. For example, “at least one of: [A], [B] and [C]” encompasses any of the following options: A alone (without B or C), B alone (without A or C), C alone (without A or B), A and B in combination (without C), A and C in combination (without B), B and C in combination (without A), or A, B and C in combination.

Although illustrative embodiments of the present techniques have been described in detail herein with reference to the accompanying drawings, it is to be understood that the present techniques are not limited to those precise embodiments, and that various changes and modifications can be effected therein by one skilled in the art without departing from the scope of the present techniques as defined by the appended claims.

1. A method of monitoring a clock signal at a circuit, the method comprising:
receiving, at a delay monitor, a gateable clock signal;
analysing, by the delay monitor, the clock signal to generate a measurement value, wherein the measurement value is responsive to the clock signal and/or a voltage; and
comparing, by the delay monitor, the measurement value with a threshold; and
storing the measurement value for further analysis when the comparison does not meet the threshold; or
discarding the measurement value when the measurement value meets the threshold.

2. The method of claim 1, wherein the method comprises:
generating a plurality of measurement values during a sampling period.

3. The method of claim 2, wherein the method comprises:
generating, by the delay monitor, a measurement value for each clock cycle within the sampling period.

4. The method of claim 2, wherein the method comprises:
generating statistical data, wherein the statistical data is based on the plurality of measurement values generated during the sampling period.

5. The method of claim 4, wherein the method comprises:
determining, by the delay monitor, from the statistical data, the maximum measurement value and/or minimum measurement value during the sampling period.

6. The method of claim 4, wherein the method comprises:
sending, by the delay monitor, the statistical data to a system control processor.

7. The method of claim 1, wherein the measurement value corresponds to the number of gates traversed by the clock signal in a delay line of the delay monitor during a clock cycle, and wherein the measurement value corresponds to the output of an encoder.

8. The method of claim 1, wherein the threshold is a programmable threshold, and wherein the method comprises:
receiving, by the delay monitor, the programmable threshold from firmware.

9. The method of claim 1, wherein the voltage is supplied by a power distribution network.

10. The method of claim 1, comprising:
determining a dynamic voltage variation based on or in response to the measurement value.

11. The method of claim 1, where the delay monitor and the circuit are driven by the same gateable clock signal.

12. A circuit for monitoring a clock signal, the circuit comprising a delay monitor configured to:
receive a gateable clock signal;
analyse the clock signal to generate a measurement value, wherein the measurement value is responsive to the clock signal and/or a voltage;
compare the measurement value with a threshold; and
in response to the comparison, the delay monitor is to:
capture the measurement value for further analysis when the comparison does not meet the threshold; or
discard the measurement value when the measurement value meets the threshold.

13. The circuit of claim 12, wherein the delay monitor is further configured to generate a plurality of measurement values during a sampling period.

14. The circuit of claim 12, wherein the delay monitor is further configured to generate a measurement value for each clock cycle within the sampling period.

15. The circuit of claim 14, wherein the delay monitor is further configured to generate statistical data, wherein the statistical data is based on the plurality of measurement values generated during the sampling period.

16. A processor comprising a circuit according to claim 12.

17. The processor of claim 16, comprising a central processor unit or a graphics processor unit.

18. A system comprising:
the circuitry of claim 12, implemented in at least one packaged chip;
at least one system component; and
a board,
wherein the at least one packaged chip and the at least one system component are assembled on the board.

19. A chip-containing product comprising the system of claim 18 assembled on a further board with at least one other product component.

20. A non-transitory computer-readable medium to store computer-readable code for fabrication of the circuitry of claim 12.
